(19) United States
(12) Patent Application Publication
(10) Pub. No.: US 2016/0205812 A1
(43) Pub. Date: Jul. 14, 2016

(54) AIR BLOCKING PANEL ASSEMBLY FOR A SERVER OR IT RACK

(71) Applicant: TATE ACCESS FLOORS LEASING, INC., Wilmington, DE (US)

(72) Inventors: Daniel J. CURTIN, Alexandria, VA (US); William W. REYNOLDS, Pasadena, MD (US); Peter STRAPP, Greenbelt, MD (US); Michael CHOI, Columbia, MD (US)

(21) Appl. No.: 14/595,639

(22) Filed: Jan. 13, 2015

(51) Int. Cl. H05K 7/20; H05K 7/14

(52) U.S. Cl. CPC H05K 7/20709; H05K 7/1489

(57) ABSTRACT

A panel assembly that is attached to the support structure of a server or IT rack. The panel assembly includes a panel and a bracket. The panel is rotatably attached to the support structure by the bracket, about a vertical axis. The panel is rotatable between open and closed positions. When in the closed position, the panel extends between two members of the server or IT rack support structure and prevents cooling airflow through the space behind the panel and between the two members. When in the open position, the panel does not impede cooling airflow through that space.

### BACKGROUND

1. Field of the Invention

This invention relates to server or IT racks that are commonly found in data centers and other facilities and building areas housing a large quantity of computer and/or other electronic equipment. In particular, this invention relates to cooling systems for such server or IT racks.

2. Background of the Invention

A typical data center includes multiple server or IT racks. Each rack usually has multiple shelves. Each shelf can support various items of computer and other electronic equipment.

The computer and other electronic equipment in server or IT racks generates a relatively high amount of heat. Providing adequate cooling air to the equipment in the server or IT racks is of paramount importance in order to prevent damage to the equipment and to enable persons to work in the data center. It is highly desirable that the computer and other electronic equipment in the server or IT racks be cooled as efficiently as possible, as energy to cool that equipment may approach a large percentage of the energy cost to operate the data center.

Often, one or more shelves or other spaces of a server or IT rack may be “empty” at a given time, i.e., there may not be any computer and other electronic equipment located on one or more shelves or in one or more spaces of a server or IT rack at a given time. In addition, the shelf, shelves or other spaces of a server or IT rack that are “empty” may change over time for at least the following reasons. The placement of computer and other electronic equipment in a given server or IT rack is often dynamic. For example, the computer and other electronic equipment in a given server or IT rack may change over time due to various factors, including adding computer capacity, system upgrades, etc. Further, the equipment in a given server or IT rack is sometimes relocated or repositioned in that rack if it is desired or necessary to change the configuration of that equipment. Thus, the “empty” shelves and other “empty” spaces in a given server or IT rack may change over time.

If a shelf or other space of a server or IT rack is “empty,” any cooling air passing immediately above that shelf or through that space will not directly cool any operating computer and other electronic equipment. That cooling air will most likely then be exhausted from the data center or other facility or building area housing that server or IT rack without directly cooling any operating equipment. The passing of the cooling air through a server or IT rack and out of the data center or other facility or building area housing that server or IT rack without directly cooling operating equipment is a waste of energy resources.

### SUMMARY OF THE INVENTION

In view of the above, there is a need to prevent or at least reduce the “waste” of cooling air in a cooling system for a server of IT rack that occurs when cooling air passes immediately above a shelf or through a space that is “empty.” In addition, because the empty shelves and other spaces of a given server or IT rack often change over time, there is a need for means to prevent or at least reduce that “waste” that is dynamic, i.e., that can selectively prevent or at least partially block cooling air from passing through shelves or other spaces that are “empty.”

This invention addresses those needs and other needs by providing a panel that is rotatably attached to the support structure of a server or IT rack by a bracket. The panel is rotatable about a vertical axis between open and closed positions. When in the closed position, the panel extends from one structural member of the support structure toward another member of the support structure and prevents or at least reduces cooling airflow through the space behind the panel and between those two members. When in the open position, the panel does not extend toward the other member of the support structure and cooling airflow through the space between those two members is not impeded by the panel.

In some embodiments of this invention, the two members of the support structure of the server or IT rack are vertical rails having a front flange, with each of the front flanges having a column of vertically spaced holes. The bracket is attached to one of the vertical rails using at least one of the vertically spaced holes.

In further embodiments of the invention, the bracket engages at least one of the vertically spaced holes of the front flange of one of the vertical rails.

In other embodiments of the invention, the bracket includes a front portion that is attached to the front flange of one of the vertical rails, a hinge portion to which the panel is rotatably attached, and a back portion with bracket openings that replicate some of the vertically spaced holes in the front flange of one of the vertical rails, with the bracket openings being spaced from the front portion.

In yet other embodiments of the invention, the bracket includes at least one protrusion that is received in at least one of the vertically spaced holes in the front flange of one of the vertical rails. The protrusion may extend all the way through one of the vertically spaced holes.

In further embodiments of the invention, the panel is an elongated panel that extends between the two vertical rails when in the closed position.

In yet other embodiments of the invention, a spring or springs may be provided that bias the panel toward the open and/or closed positions. The panel may include a tab or tabs that is/are configured to be received in and engage one of the vertically spaced holes to retain the panel in the closed position.

### BRIEF DESCRIPTION OF THE DRAWINGS

FIG. 1 is a front perspective view of a plurality of panel assemblies according to one embodiment of this invention, attached to rails of a server or IT rack.

FIG. 2 is a front perspective view of the plurality of panel assemblies of FIG. 1, again attached to rails of a server or IT rack, showing one of the panel assemblies moving from the closed position to the open position.

FIG. 3 is a front perspective view of the bracket of the panel assemblies of FIGS. 1 and 2.

FIG. 4 is a rear perspective view of the bracket of FIG. 3.

FIG. 5 is a front perspective view of the panel of the panel assemblies of FIGS. 1 and 2.

FIG. 6 is a rear perspective view of the panel of FIG. 5.

FIG. 7 is a partial, exploded, front perspective view of the attachment of the panel of FIGS. 5 and 6 to the bracket of FIGS. 3 and 4.

FIGS. 8 and 9 are partial front views of the attachment of the bracket of FIGS. 3 and 4 to a vertical rail of a server or IT rack.

FIG. 10 is a partial view of a plurality of panel assemblies of FIGS. 1-9 attached to a vertical rail of a server or IT rack, illustrating the panel assemblies in various positions vis-à-vis the server or IT rack.

FIG. 11 is a front perspective view of another embodiment of a bracket that can be included in the panel assemblies of this invention.

FIG. 12 is a rear perspective view of the bracket of FIG. 11.

FIG. 13 is a front perspective view of another embodiment of a bracket that can be included in the panel assemblies of this invention.

FIG. 14 is a rear perspective view of the bracket of FIG. 13.

FIG. 15 is a front perspective view of a plurality of panel assemblies according to a second embodiment of this invention, attached to rails of a server or IT rack.

FIG. 16 is a front perspective view of another embodiment of a panel that can be included in the panel assemblies of this invention.

FIG. 17 is a rear perspective view of the panel of FIG. 16.

FIG. 18 is a front perspective view of yet another embodiment of a panel that can be included in the panel assemblies of this invention.

FIG. 19 is a perspective view of an embodiment of a clip that can be utilized to attach a bracket of this invention to a vertical rail of a server or IT rack.

FIG. 20 is a perspective view of another embodiment of a clip that can be utilized to attach a bracket of this invention to a vertical rail of a server or IT rack.

FIG. 21 is a front perspective view of a panel assembly according to another embodiment of this invention.

FIG. 22 is an exploded view of the panel assembly of FIG. 21.

FIG. 23 is a front perspective view of one end of the panel assembly of FIGS. 21 and 22.

FIG. 24 is an end view of the panel assembly of FIGS. 21-23.

FIG. 25 is a front perspective view of the panel of the panel assembly of FIGS. 21-24.

FIG. 26 is a front perspective view of the bracket of the panel assembly of FIGS. 21-25.

FIG. 27 is a rear elevation view of the bracket of FIG. 26.

FIG. 28 is a front perspective view of the spring of the panel assembly of FIGS. 21-27.

### DETAILED DESCRIPTION OF THE DRAWINGS

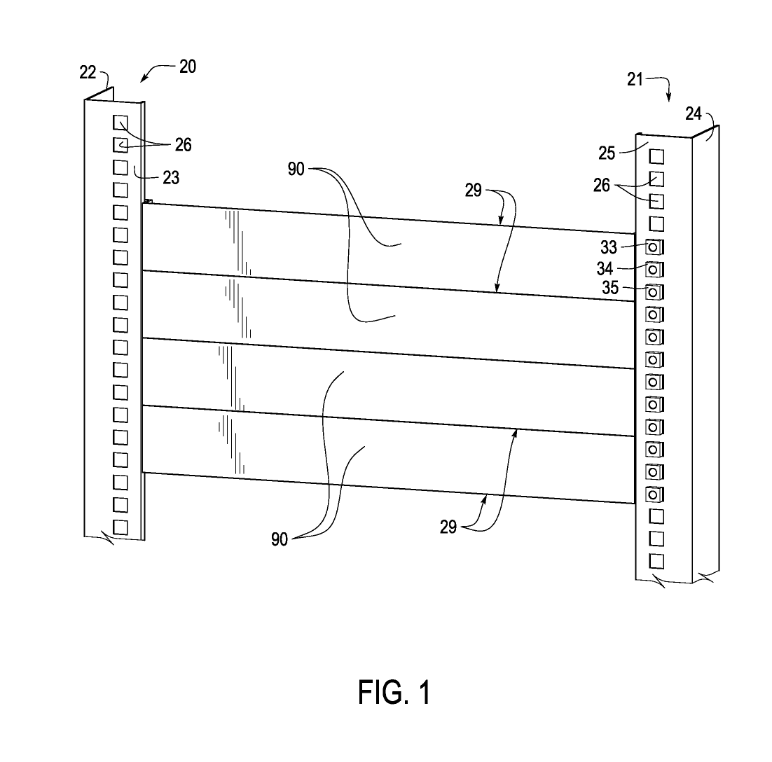

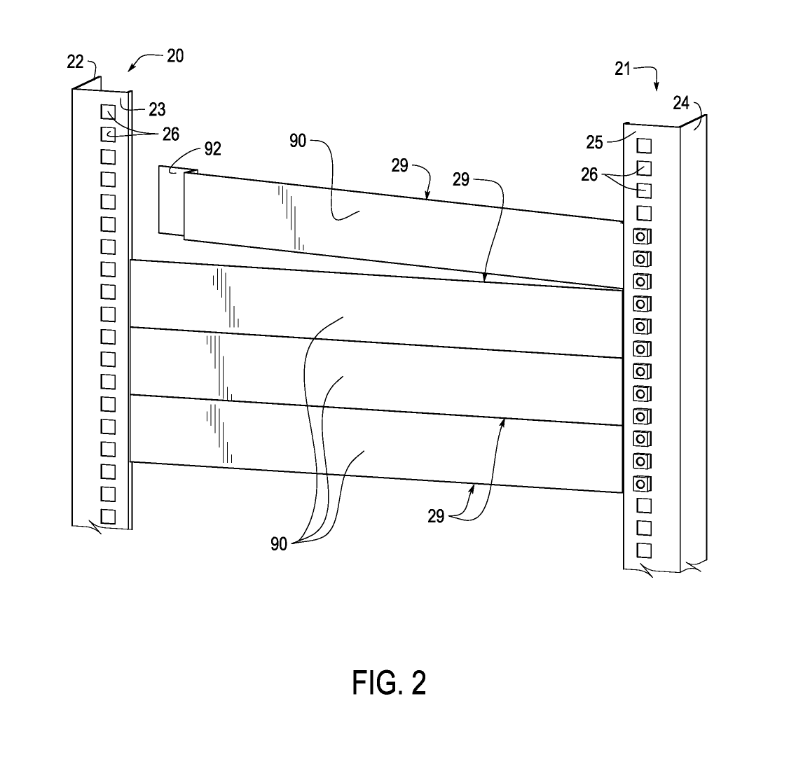

A typical server or IT rack includes spaced, parallel, front vertical rails, such as vertical rails 20 and 21 illustrated in FIGS. 1 and 2. Such vertical rails are usually generally L-shaped, with a front flange and a side flange. In FIGS. 1 and 2, vertical rail 20 includes front flange 23 and side flange 22, and vertical rail 21 includes front flange 25 and side flange 24.

In addition, such vertical rails are usually oriented such that their respective side flanges are parallel and their respective front flanges extend towards each other. In that regard, in FIGS. 1 and 2, side flanges 22 and 24 are parallel and front flanges 23 and 25 extend towards each other.

Finally, the front flanges of such vertical rails usually include a vertical column of equally spaced holes. Those holes are intended to be engaged by shelf assemblies that support computer and other equipment in the space between and behind the vertical rails. In that regard, each of front flanges 23 and 25 includes a column of equally spaced holes 26.

While the embodiments of this invention described herein are for use with server or IT racks that include front, parallel, vertical, L-shaped rails having a column of equally spaced holes in their front flanges, such as rails 20 and 21, other embodiments of the invention can be used with server or IT racks that do not include those rails. For example, other embodiments of the invention can be used with rails or other structural members that are not vertical, with rails or other structural members that are not parallel, with rails or other structural members that are not L-shaped, and with rails or other structural members that do not include a column of spaced holes.

As discussed above, this invention is a panel assembly that attaches to the support structure of a server or IT rack. The embodiment of this invention illustrated in the FIGS. 1-10 is panel assembly 29, which is attachable to rails 20 and 21.

Panel assembly 29 includes bracket 30 that is attachable to a vertical rail of a server or IT rack, such as vertical rail 21, panel 90 that is rotatably attached to bracket 30, and spring 94. Panel 90 is rotatably attached to bracket 30 by pin or rod 31. Spring 94 is received on pin or rod 31 and biases panel 90 in the closed position, as discussed below.

This invention is not limited to panel assemblies comprised of a single panel rotatably attached to a single bracket. Rather, other embodiments of this invention may include more than one panel rotatably attached to a single bracket, or one or more panels rotatably attached to a bracket of multiple components. Also, the panels(s) can be rotatably attached to the bracket(s) by a mechanism other than a pin or rod. Finally, the panel or panels do not have to be rotatably attached to the bracket(s).

Moreover, the panel assembly does not have to have a spring or any other mechanism that biases the panel in the closed or open positions. Rather, the panel can be unbiased vis-à-vis the bracket.

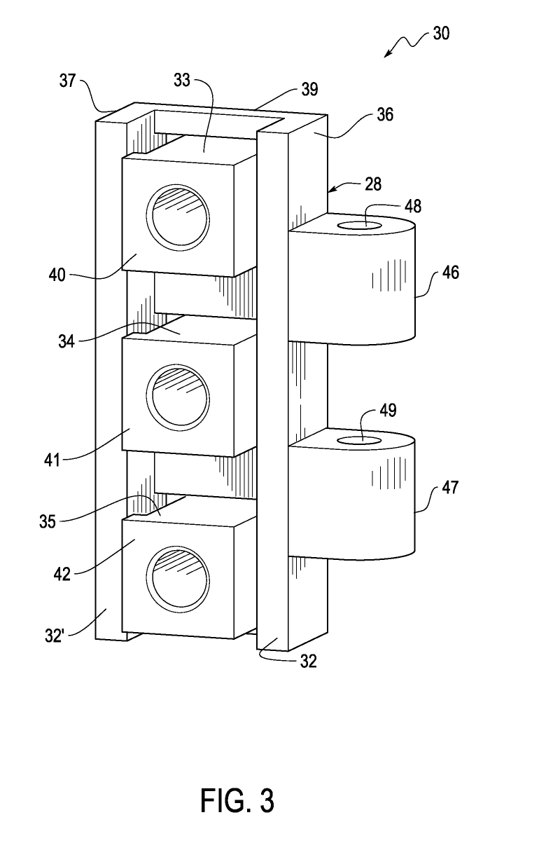

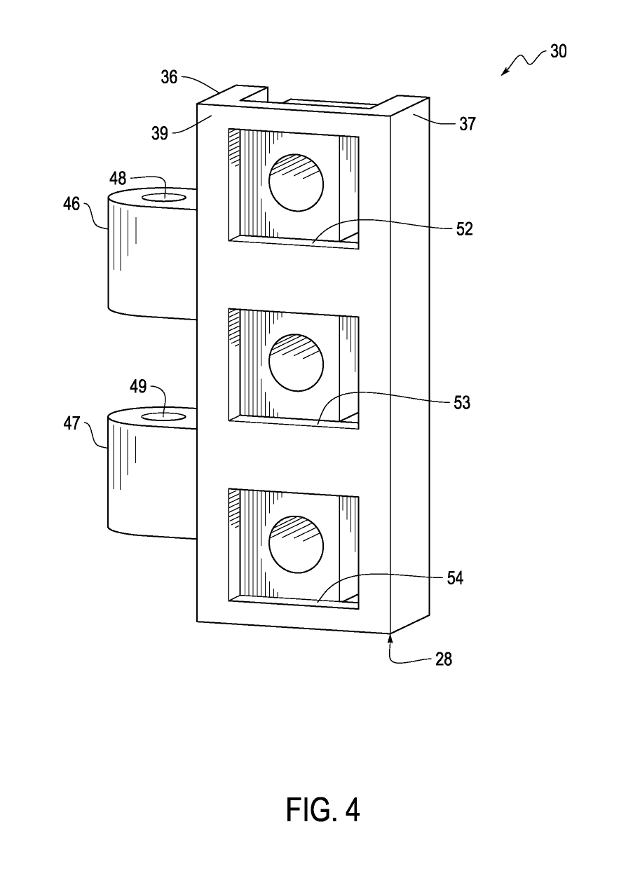

Bracket 30 is illustrated in FIGS. 3 and 4. Bracket 30 includes vertical support member 28, front protrusions 33, 34 and 35 and hinge members 46 and 47.

Vertical support member 28 includes side walls 36 and 37 and back wall 39. Side walls 36 and 37 are parallel and have front faces 32 and 32′, respectively. Back wall 39 extends between side walls 36 and 37.

Back wall 39 includes holes 52, 53 and 54. See FIG. 4. Holes 52, 53 and 54 are substantially the same size and have substantially the same spacing as holes 26 in front flanges 23 and 25 of vertical rails 20 and 21, respectively, for the reasons discussed below.

Front protrusions 33, 34 and 35 are supported by and positioned between side walls 36 and 37. Front protrusions 33, 34 and 35 can be integral with side walls 36 and 37, or they can be separate members that are attached to side walls 36 and 37.

Front protrusions 33, 34 and 35 are sized and located to be received in and protrude through holes 26 in vertical rails 20 and 21, as discussed below.

There are holes through front protrusions 33, 34 and 35 for the following reason. Sometimes computer and other electronic equipment is attached to the vertical rails of a server or IT rack utilizing the holes in those rails, such as holes 26 in rails 20 and 21. For example, bolts that pass through holes 26 can be used to attach computer or other electronic equipment to rails 20 and 21. The inclusion of the holes through front protrusions 33, 34 and 35 means that bracket 30 will not preclude or interfere with that practice. That is, the bolts or other fasteners can pass through the holes in front protrusions 33, 34 and 35 and the holes in the vertical rails, such as holes 26, to fasten computer and other electronic equipment to the vertical rails.

Each of front protrusions 33, 34 and 35 includes an enlarged front face 40, 41 and 42, respectively, such that a shoulder is formed by the back face of each of enlarged front faces 40, 41 and 42 and the rest of front protrusions 33, 34 and 35, respectively. In this embodiment, enlarged front faces 40, 41, and 42 extend beyond the rest of front protrusions 33, 34 and 35 on only one side of front protrusions 33, 34 and 35, respectively, for the reason discussed below.

Hinge members 46 and 47 are attached to or integral with side wall 36. Hinge members 46 and 47 include vertically aligned cylindrical holes 48 and 49, respectively, for receipt of pin or rod 31.

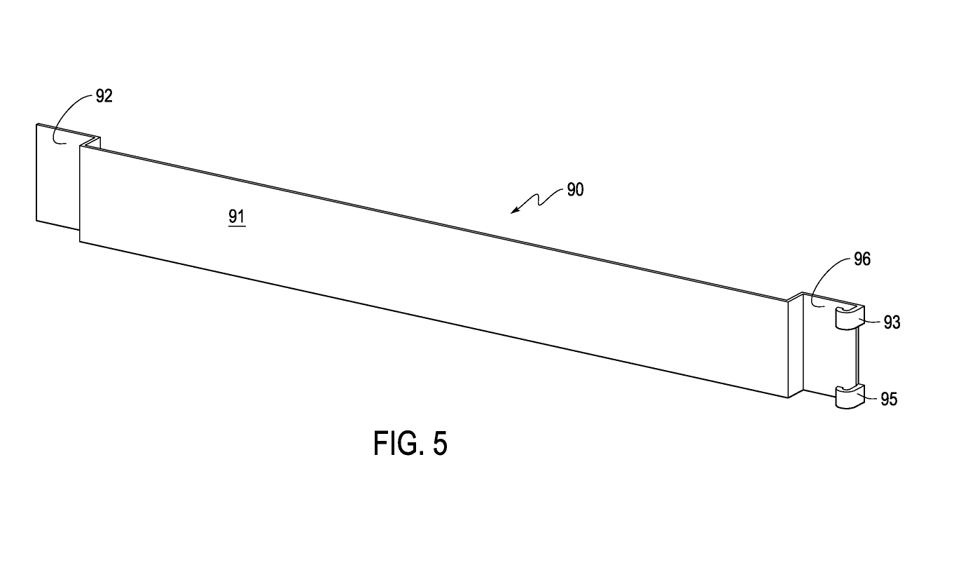

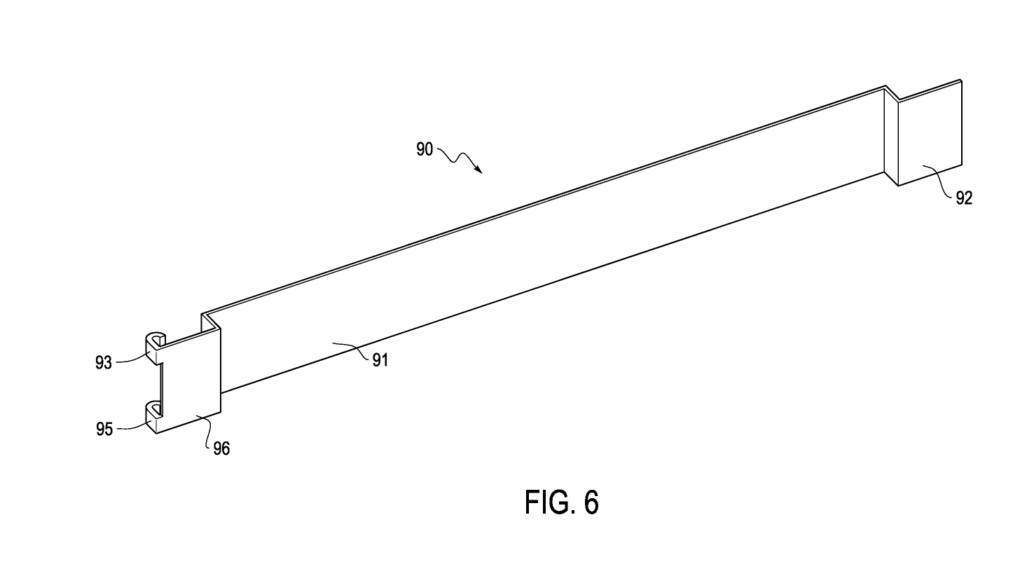

Panel 90 is illustrated in FIGS. 5 and 6. Panel 90 includes flat center section 91, recessed end portion 92, recessed end portion 96 and hinge fingers 93 and 95.

Recessed end portions 92 and 96 are at opposite ends of flat center section 91 and are recessed from flat center section 91 (when viewed from the front) so that support members of a server or IT rack, such as vertical rails 20 and 21, can be received in recessed end portions 92 and 96, as illustrated in FIGS. 1, 2 and 8-10.

In some embodiments, the flat center section may have one or more reinforcing members or structure on the front and/or back side thereof, such as reinforcing ribs.

Hinge fingers 93 and 95 are a continuation of recessed end portion 96, and form a vertically aligned cylinder for receipt of a pin or rod, such as pin or rod 30. Hinge fingers 93 and 95 and hinge members 46 and 47 of bracket 30 are sized and shaped such that (1) hinge member 46 is received immediately below hinge finger 93 and (2) hinge member 47 is received immediately above hinge finger 95.

Panel 90 can be injection molded, cast, stamped or produced in any other suitable manner.

Spring 94 is a coil spring located on pin or rod 31 between hinge members 46 and 47 and interacts with bracket 30 and panel 90 to bias panel 90 toward the closed position. While in this embodiment, spring 94 is a coil spring utilized much like a coil spring in a conventional mousetrap, any other type of spring can be employed that is suitable to bias panel 90 toward the closed position.

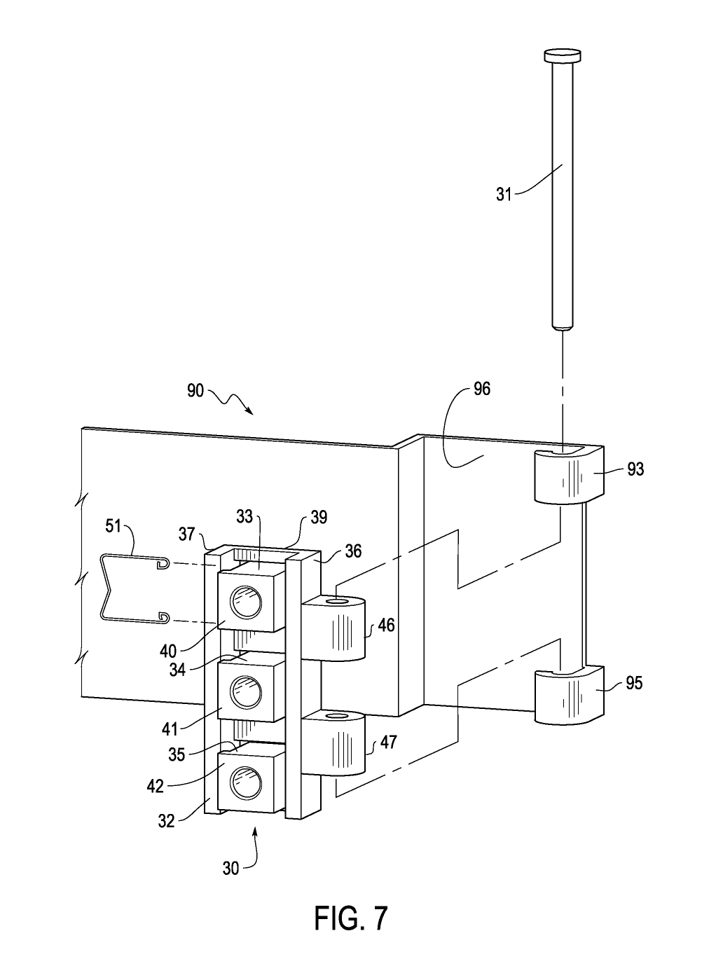

Panel 90 is attached to bracket 30 as shown in FIG. 7 and described below. Hinge member 46 of bracket 30 is placed immediately below hinge finger 93 of panel 90, and hinge member 47 of bracket 30 is placed immediately above hinge finger 95 of panel 90, such that holes 48 and 49 of hinge members 46 and 47, respectively, are in substantial alignment with the vertical cylinder formed by hinge fingers 93 and 95. Spring 94 is positioned between hinge members 46 and 47.

Pin or rod 31 is then inserted through holes 48 and 49, hinge fingers 93 and 95 and spring 94. Pin or rod 31 can be a short rod that is received by a single bracket 30, or it can be a longer rod that extends through a plurality of brackets 30.

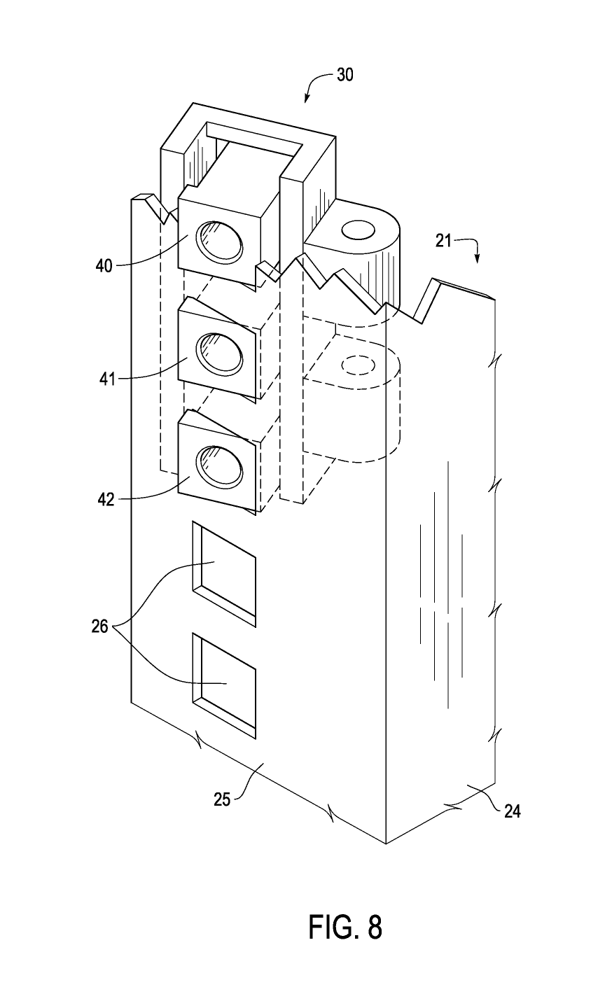

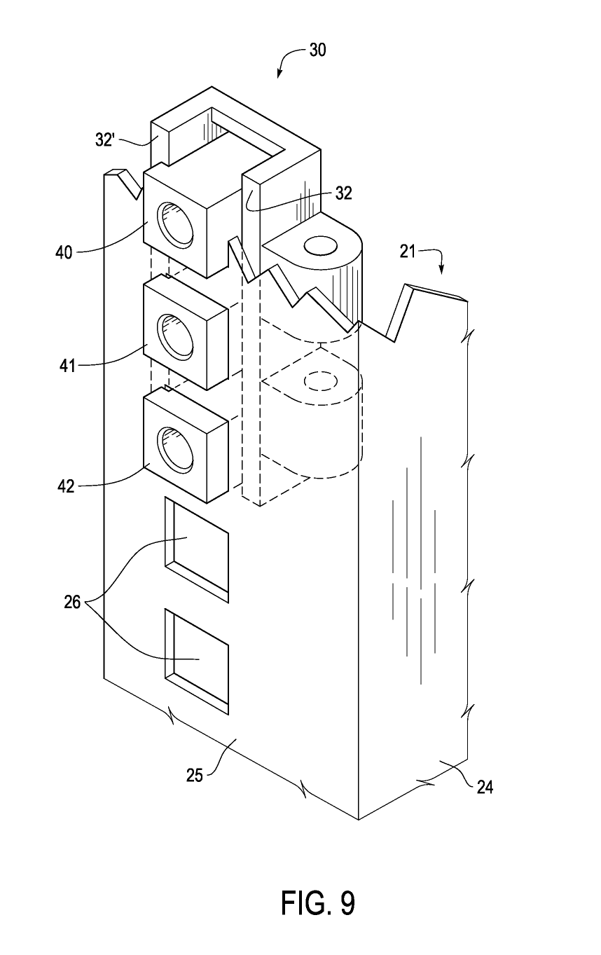

Bracket 30 is attached to vertical rail 21 as shown in FIGS. 8 and 9 and described below.

Front protrusions 33, 34 and 35 of bracket 30 are aligned with three adjacent holes 26 in front flange 25 of vertical rail 21. Front protrusions 33, 34 and 35 are then inserted into those three holes 26 at an angle, as shown in FIG. 8, because enlarged face portions 40, 41 and 42 of front protrusions 33, 34 and 35, respectively, are wider than holes 26. Once enlarged face portions 40, 41 and 42 are inserted through the three adjacent holes 26, bracket 30 is rotated horizontally until front face surfaces 32 and 32′ are substantially parallel to the back of front flange 25, as shown in FIG. 9.

A spring clip, such as spring clip 51 shown in FIG. 7, is inserted around each of front protrusions 33, 34 and 35, behind front flange 25 of vertical rail 21, to retain bracket 30 in engagement with front flange 25.

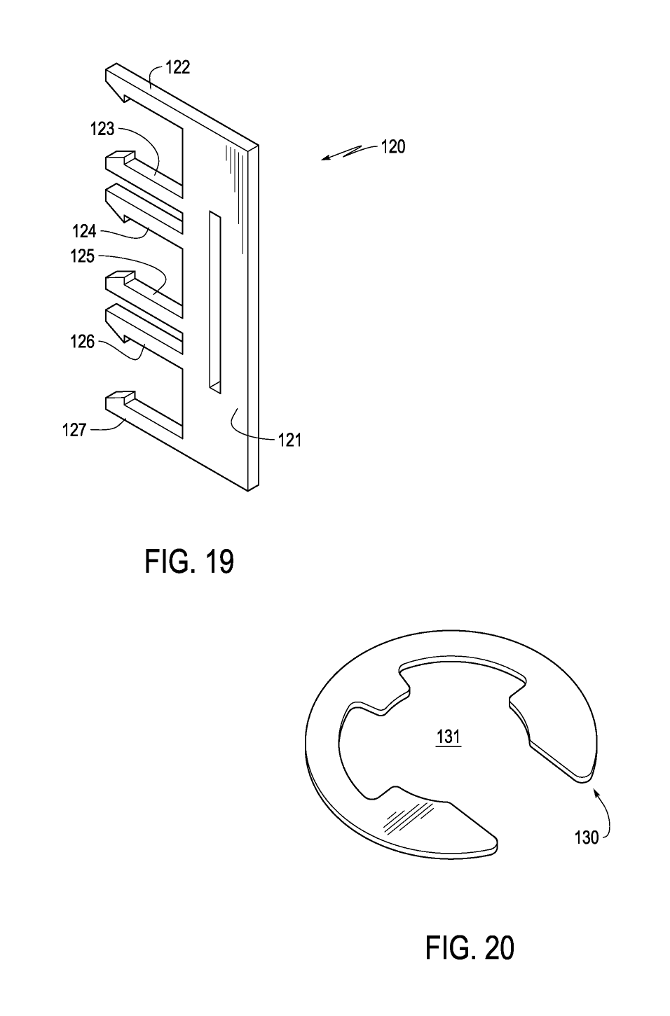

Other mechanisms that can be utilized to attach bracket 30 to front flange 25 include lock washers, such as lock washer 120 illustrated in FIG. 19. Lock washer 120 includes base 121 and resilient fingers 122-127 that extend in the same direction from base 121. Fingers 122-127 are designed and configured to engage front protrusions 33, 34 and 35 behind enlarged faces 40, 41 and 42, respectively. Specifically, fingers 122 and 123 engage front protrusion 33 behind enlarged face 40, fingers 124 and 125 engage front protrusion 34 behind enlarged face 41, and fingers 126 and 127 engage front protrusion 35 behind enlarged face 42.

Yet other mechanisms that can be utilized to attach bracket 30 to front flange 25 include off-the-shelf retaining rings, such as retaining ring 130 illustrated in FIG. 20. Retaining ring 130 is configured to receive a front protrusion 33, 34 or 35 behind an enlarged face 40, 41 or 42, respectively, in the opening 131.

In other embodiments of this invention, engagement mechanisms other than spring clips, lock washers and retaining rings can be utilized to ensure that front protrusions 33, 34 and 35 are retained in place vis-à-vis front flange 25.

Usually, panel 90 will be attached to bracket 30 before bracket 30 is attached to vertical rail 21.

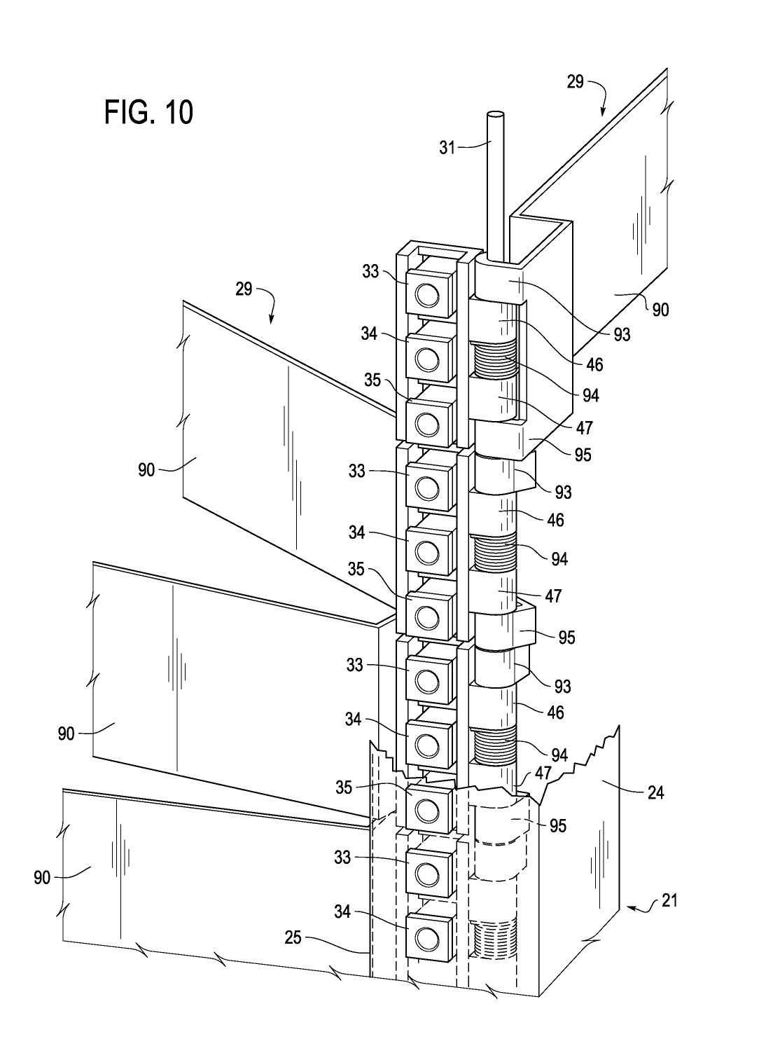

As described above, in panel assembly 29, panel 90 is rotatably attached to bracket 30 by pin or rod 31. Bracket 30 is fixedly attached to rail 21. Thus, panel 90 can be swung or rotated around rail 21 and bracket 30 between closed and open positions as desired, as shown in FIGS. 1, 2 and 10. More specifically, in FIG. 10, the top panel 90 is in the open position and the bottom panel 90 is in the closed position. The middle two panels 90 are in the process of being swung between the closed and open positions. As discussed above, spring 94 biases panel 90 toward the closed position.

When panel 90 is in the closed position, panel 90 extends between rails 20 and 21. Recessed end portion 92 of panel 90 abuts rail 20.

Panel 90 is intended to be in the closed position when there is no computer and/or other electronic equipment in the space behind panel 90.

Under those circumstances, when in the closed position, panel 90 will prevent or at least reduce cooling airflow into the space directly behind panel 90 and thus prevent cooling air from passing through that space without directly cooling operating computer and/or other electronic equipment or at least reduce the volume of air that passes through that space without directly cooling operating computer and/or other electronic equipment. That will improve the cooling efficiency and reduce the cooling costs for a data center and any other facility or building area in which panels 90 are employed with server or IT racks.

Conversely, when there is computer and/or other electronic equipment in the space containing panel 90, it is intended that panel 90 be in the open position. When panel 90 is in the open position, cooling air enters the space containing panel 90 unimpeded.

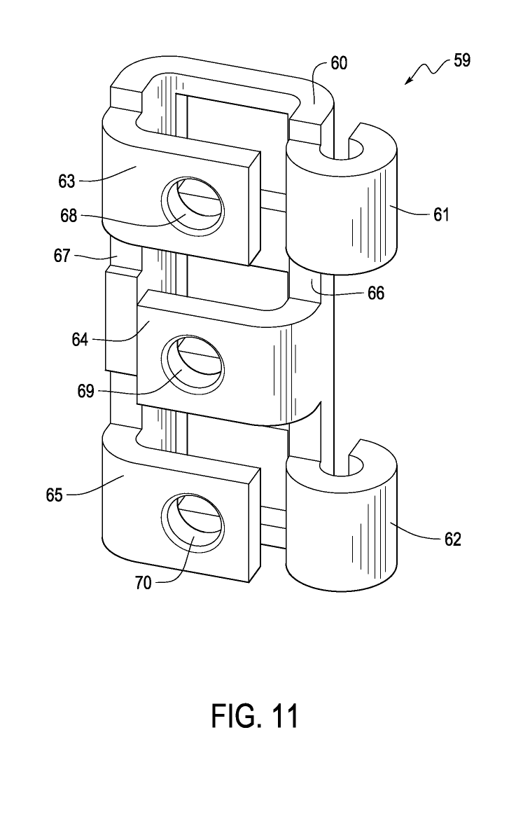

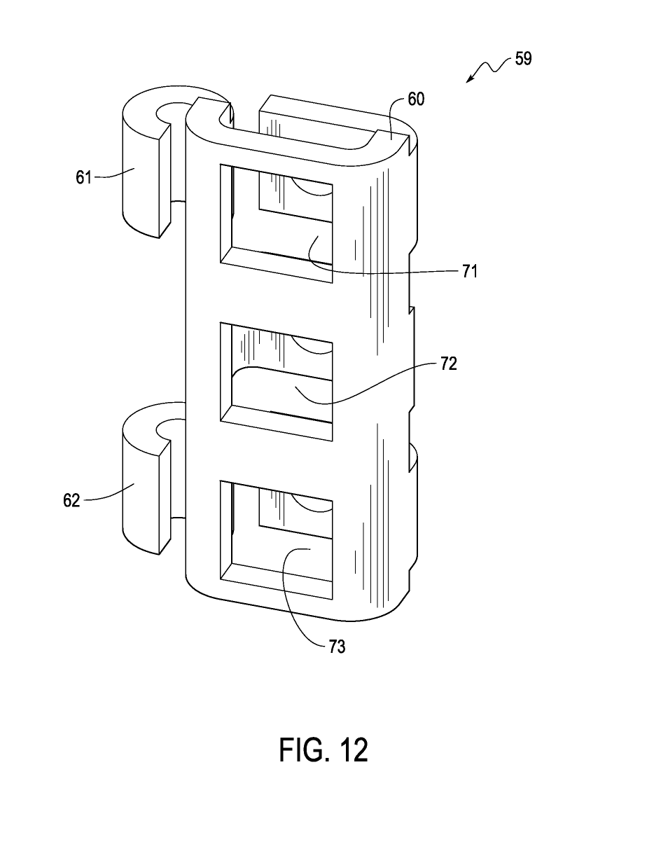

Another embodiment of a bracket that can be used in a panel assembly of this invention is bracket 59, illustrated in FIGS. 11 and 12. Bracket 59 includes U-shaped back portion 60, hinge fingers 61 and 62 and rail engaging portions 63, 64 and 65.

U-shaped back portion 60 has front faces 66 and 67. Hinge fingers 61 and 62 extend from front face 66 and rail engaging portions 68-70 extend from front face 67. Hinge fingers 61 and 62 and rail engaging portions 68-70 can be integral with U-shaped back portion 60, or they can be separate members that are attached to U-shaped back portion 60.

U-shaped back portion 60 includes holes 71, 72 and 73, which are substantially the same size and have substantially the same spacing as holes 26 in front flanges 23 and 25 of vertical rails 20 and 21, respectively, for the reasons discussed below.

Hinge fingers 61 and 62 form a vertical cylinder for receipt of a pivot pin or rod.

Rail engaging portions 63, 64 and 65 include holes 68, 69 and 70, respectively, for the following reason. Rail engaging portion 63, 64 and 65 can be attached to front flange 23 of vertical rail 20 or front flange 25 of vertical rail 21 by bolt assemblies or other fasteners that pass through holes 68, 69 and 70 and holes 26.

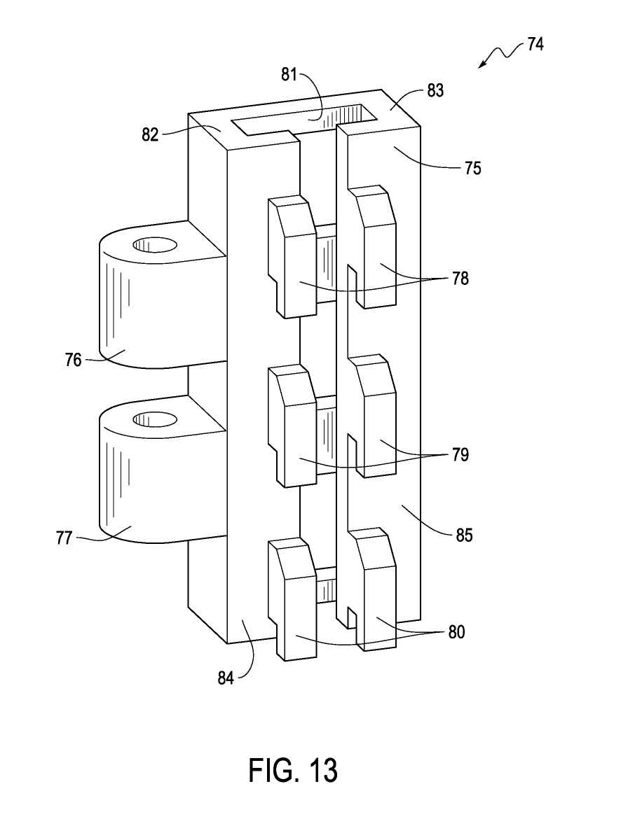

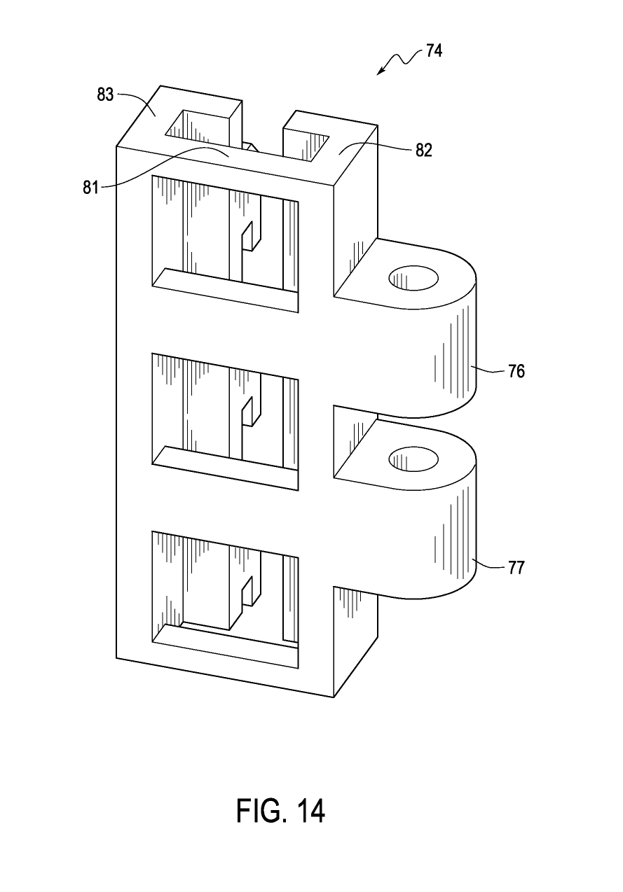

Another embodiment of a bracket that can be used in a panel assembly of this invention is illustrated in FIGS. 13 and 14, bracket 74. Bracket 74 includes C-shaped brace 75, hinge portions 76 and 77 and pairs of hooks 78, 79 and 80.

C-shaped brace 75 includes back wall 81, side walls 82 and 83 and front lips 84 and 85.

Back wall 81 includes holes 86, 87 and 88, which are substantially the same size and have substantially the same spacing as holes 26 in perpendicular flanges 23 and 25 of vertical rails 20 and 21, respectively, for the reasons discussed below.

Hinge portions 76 and 77 are attached to side wall 82, or are integral therewith.

Pairs of hooks 78, 79 and 80 extend from front lips 84 and 85. Specifically, one hook of each of the pairs of hooks, 78, 79 and 80 is attached to or integral with front lip 84, and extends therefrom, and the other hook of each of pairs of hooks 78, 79 and 80 is attached to or integral with front lip 85, and extends therefrom.

Bracket 74 is attached to one of vertical rail 20 or vertical rail 21 by inserting pairs of hooks 78, 79 and 80 into adjacent holes 26 and then sliding bracket 74 downward until the lower edges of holes 26 are received by pairs of hooks 78, 79 and 80.

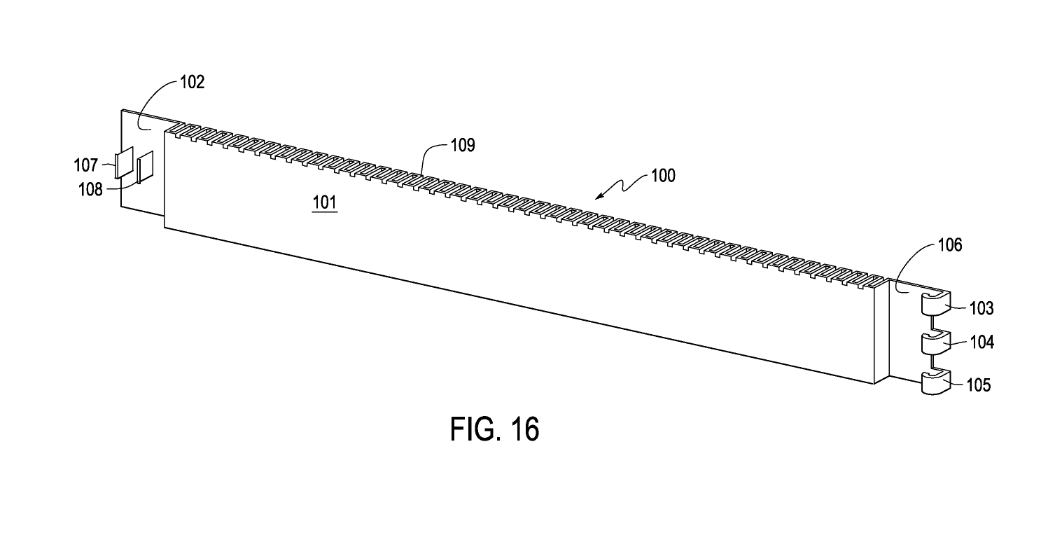

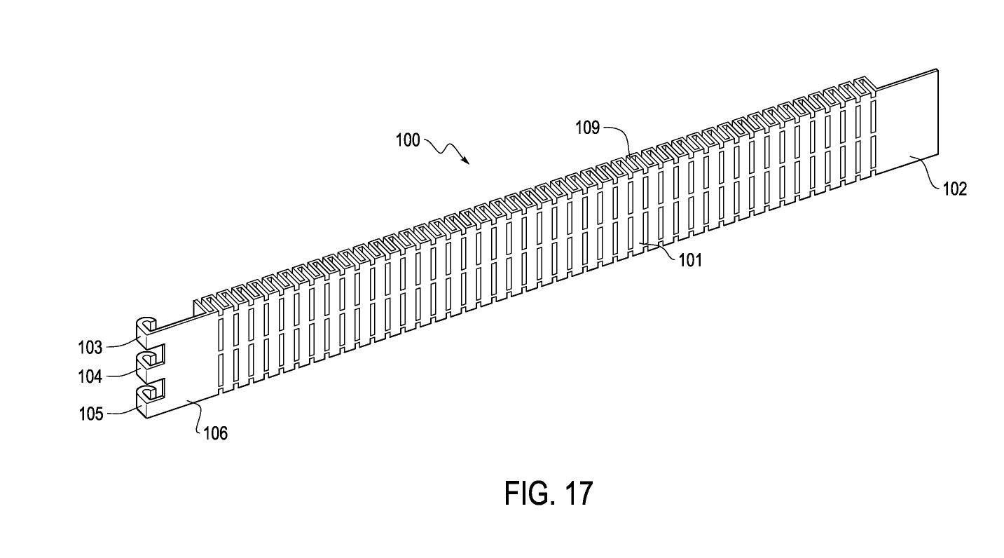

Another embodiment of a panel that can be used in a panel assembly of this invention is illustrated in FIGS. 16 and 17, panel 100. Panel 100 includes front plate 101, recessed end portion 102, recessed end portion 106, hinge fingers 103, 104 and 105, and honeycomb supporting structure 109. Panel 100 is not designed to be used in a panel assembly having a spring that biases panel 100 in the open or closed position. In effect, the spring is replaced by the third hinge finger, hinge finger 104.

Recessed end portions 102 and 106 are at opposite ends of front plate 101 and are recessed from front plate 101 (when viewed from the front) so that support members of a server or IT rack, such as vertical rails 20 and 21, can be received in recessed end portions 102 and 106 when panel 100 is in the closed position. Honeycomb supporting structure 109 is on the backside of front plate 101 to add rigidity.

Recessed end portion includes tabs 107 and 108. Tabs 107 and 108 are received in and removably engage one of the holes in the vertical rails of a server or IT rack, such as holes 26 in rail 20, to attach panel 100 to that vertical rail. Not only does that attachment affix panel 100 to the vertical rail of a server or IT rack, that attachment also helps with the alignment of panel 100 vis-à-vis the server or IT rack.

While, in this embodiment, tabs 107 and 108 are utilized to attach one end of panel 100 to a vertical rail of a server or IT rack, in other embodiments of the panel assemblies of this invention, any other suitable attachment mechanism can be used that attaches the panel to the vertical rail.

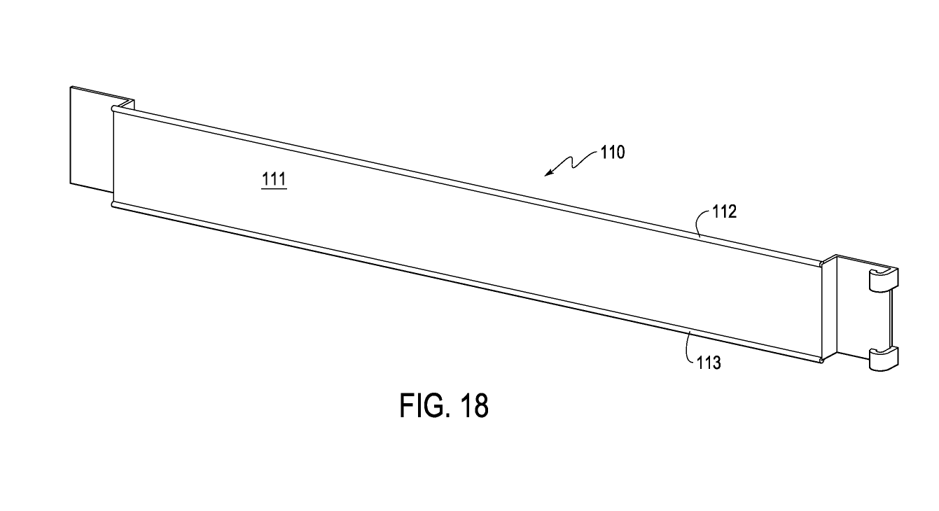

Yet another embodiment of a panel that can be used in a panel assembly of this invention is illustrated in FIG. 18, panel 110. Panel 110 is the same as panel 90, except panel 110 includes gaskets or seals 111 and 112 along the top and bottom edges of flat plate 111 of panel 110, respectively. Alternatively, panel 110 can be supplied with only gasket or seal 111, only gasket or seal 112, or one or more gaskets or seals may be provided on the backside of the panel 111, instead of or in addition to the seals on the front side. Seals 112 and 113 are designed to interface with adjacent panels to present an airtight seal between adjacent panels.

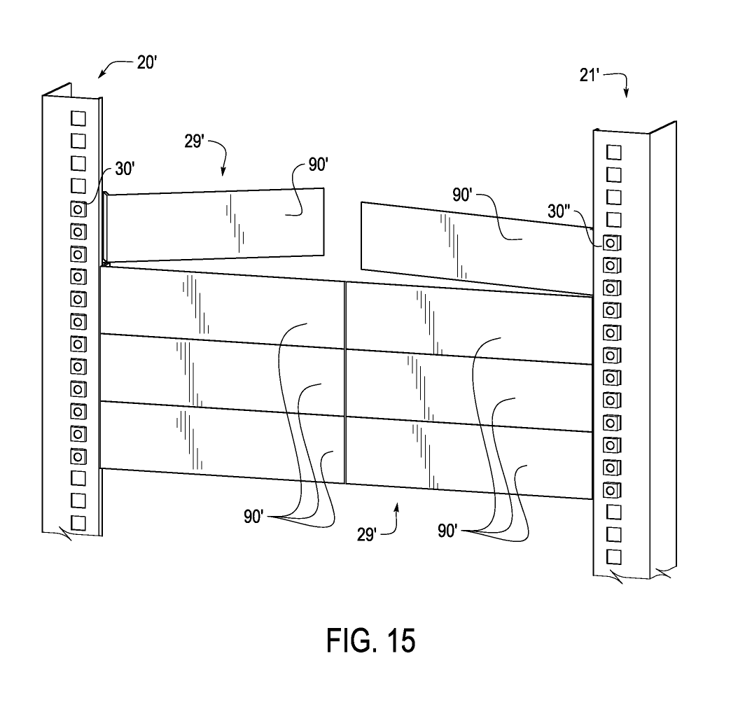

As stated above, another embodiment of a panel assembly of this invention is illustrated in FIG. 15, panel assembly 29′. Panel assembly 29′ includes two brackets, brackets 30′ and 30″, attached to rails 20′ and 21′, respectively. A panel 90′ is attached to each bracket 30′ and 30″. Panels 90′ extend approximately one-half of the distance between rails 20′ and 21′, as illustrated by FIG. 15. Each of panels 90′ can be independently rotated between open and closed positions. Panels 90′ may have a mechanism or mechanisms on their free ends that attach the free ends, and/or one or more gaskets or seals at their free ends that seals the joint between the free ends.

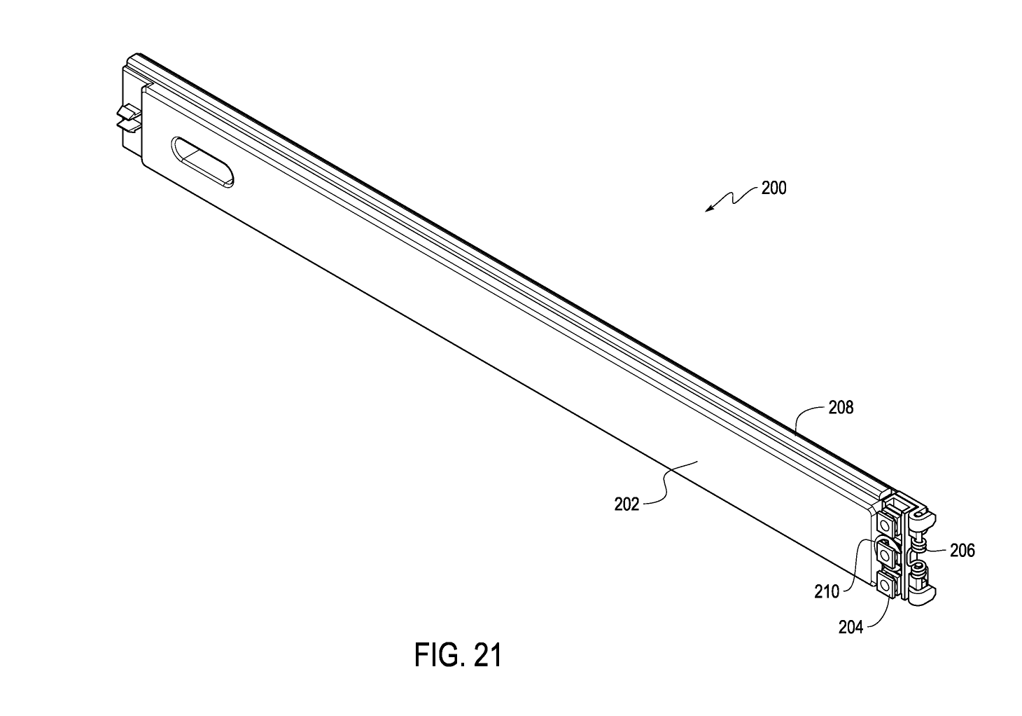

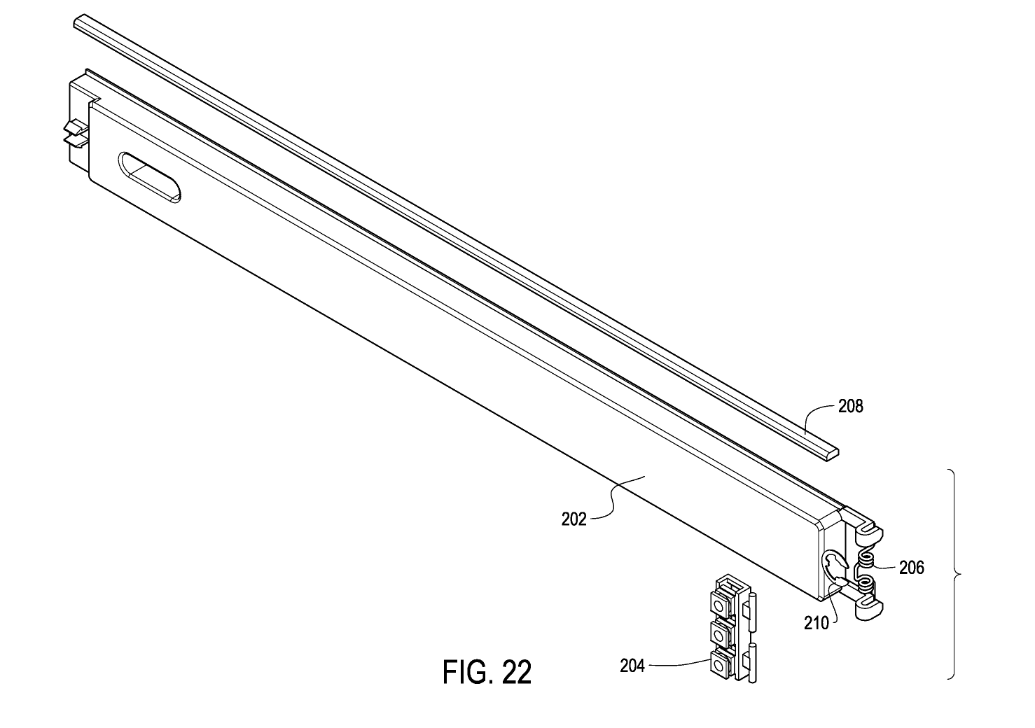

As stated above, another embodiment of a panel assembly of this invention is illustrated in FIGS. 21-28, panel assembly 200. Panel assembly 200 includes panel 202, bracket 204, spring 206, seal or gasket 208, and retaining clip 210. Panel assembly 200 is rotatably attached to a vertical rail of a server or IT rack by bracket 204.

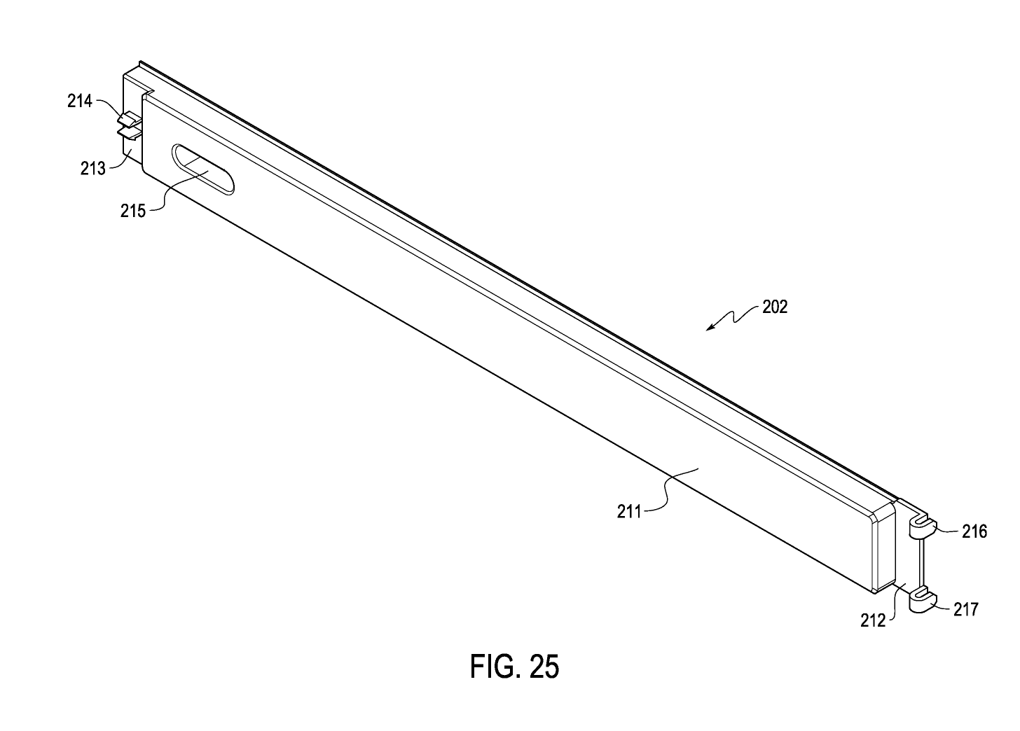

Panel 202 is illustrated in FIG. 25. Panel 202 includes flat center section 211 having handhold 215, recessed end portion 212, recessed end portion 213 with tabs 214, and hinge fingers 216 and 217. Panel 202 can have a honeycomb construction for enhanced structural stability, if desired.

Recessed end portions 212 and 213 are at opposite ends of flat center section 211 and are recessed from the front surface of flat center section 211 (when viewed from the front), so that support members of a server or IT rack, such as vertical rails 20 and 21, can be received in recessed portions 212 and 213.

In this embodiment, hinge fingers 216 and 217 are a continuation of recessed end portion 212 and form a vertically aligned cylinder for receipt of the ends of spring 206.

Tabs 214 are resilient and extend outwardly from recessed end portion 213 to engage an opening in the structural members of a server or IT rack, such as one of the holes 26 in vertical rail 20.

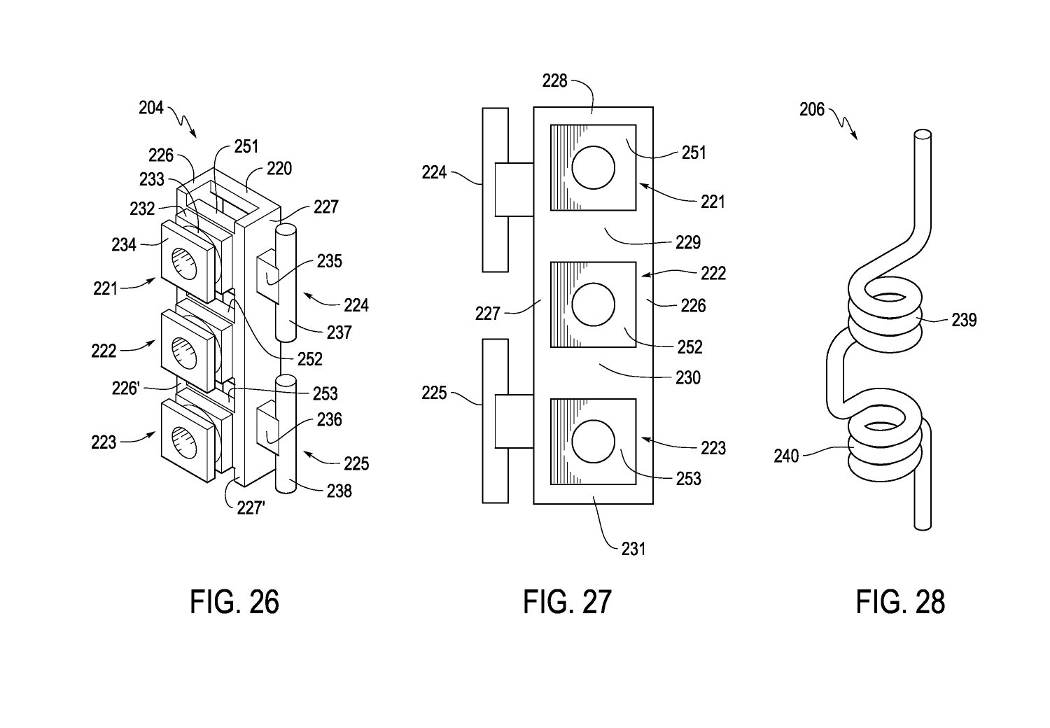

Bracket 204 is illustrated in FIGS. 26 and 27. Bracket 204 includes support frame 220, center protrusions 221, 222 and 223, and side rod assemblies 224 and 225.

Support frame 220 includes side walls 226 and 227 joined by spaced, back, cross support members 228, 229, 230 and 231 and spaced, front cross support members 251, 252 and 253. Side walls 226 and 227 have front faces 226′ and 227′, respectively.

Center protrusions 221, 222 and 223 are supported by front cross support members 251, 252 and 253, respectively. Side rod assemblies 224 and 225 extend outwardly from side wall 227.

Each center protrusion 221, 222 and 223 includes base 232, which is attached to one of front cross support members 251, 252 and 253, neck 233 and front plate 234. Base 232 extends in front of the front faces 226′ and 227′ of side walls 226 and 227 a distance greater than the thickness of the vertical rails of IT or server racks. Neck 233 is smaller than base 232 and front plate 234 so that retaining clip 210 is received around neck 233 between base 232 and front plate 234.

Side rod assemblies 224 and 225 include support extensions 235 and 236 and vertical rods 237 and 238, respectively. Support extensions 235 and 236 position vertical rods 237 and 238 relative to side wall 227.

Spring 206 is illustrated in FIG. 28 and includes coils 239 and 240.

Panel assembly 200 is assembled as follows, albeit not necessarily in this order. Seal or gasket 208 is attached to the top of panel 202. Spring 206 is placed on rods 237 and 238. Specifically, coil 239 is placed on rod 237 below support extension 235 and coil 240 is placed on rod 238 above support extension 236.

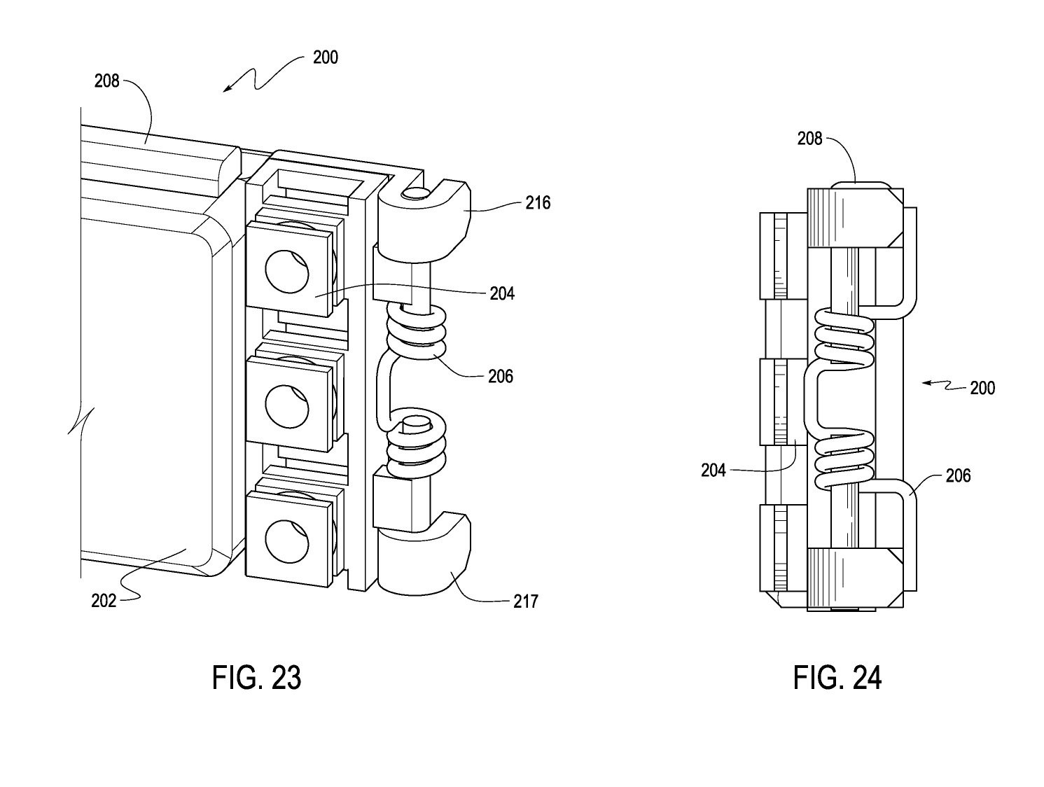

Bracket 204 is attached to panel 202 by (1) inserting the top of rod 237, i.e., the portion of rod 237 above support extension 235, into hinge finger 216 and (2) inserting the bottom of rod 238, i.e., the portion below support extension 236, into finger 217, as shown in FIG. 23.

Panel assembly 200 is attached to a support member of a server or IT rack by inserting protrusions 221, 222 and 223 though adjacent holes in the support member until front faces 226′ and 227′ of side walls 226 and 227 interface with the back surface of the support member. At least one clip 210 is then placed around a neck 233.

Panels 90, 90′, 100, 110 and 202 and brackets 30, 30′, 30″, 59, 74 and 204 are examples of the panels and brackets that can comprise the panel assemblies of this invention. However, any bracket can be employed (1) that can be affixed to a server or IT rack and (2) to which a panel can be attached. Also, any panel can be employed that effectively prevents cooling airflow through the space behind the panel when the panel is in the closed position. For example, one option is a panel that folds as well as rotates around a bracket.

The embodiments of the invention described above and illustrated by the figures are described and illustrated as being attached to front rails of a server or IT rack, with the front of the rack being defined as the face of the rack that faces a cool aisle. Those embodiments, and other embodiments of the invention, can be attached to the rear rails of a server or IT rack, if desired.

One advantage of the embodiments of this invention specifically described above and illustrated by the figures is that the panel assemblies of those embodiments can be retrofitted onto most existing server or IT racks or can be pre-installed on new server or IT racks.

Another advantage of the embodiments of this invention specifically described above and illustrated by the figures is that computer and other electronic equipment can be installed in a server or IT rack having one or more panel assemblies of those embodiments without removing those panel assemblies.

Yet another advantage of the embodiments of this invention specifically described above and illustrated by the figures is that the functionality of the vertical rails to which the panel assemblies are attached is not compromised by the addition of the panel assemblies. More specifically, as discussed above, one function of the vertical columns of holes in vertical rails of a server or IT rack, such as the columns of holes 26 in front flanges 23 and 25, is to receive shelving assemblies. Because the brackets of the embodiments of this invention specifically described above and illustrated by the figures, i.e., brackets 30, 30′, 30″, 59, 74 and 204, have a series of holes in the back wall thereof that replicate a series of holes 26 (see, e.g., (1) holes 52, 53 and 54 in back wall 39 of bracket 30, (2) holes 71, 72 and 73 in U-shaped back portion 60 of bracket 59, and (3) holes 86, 87 and 88 in base 75 of bracket 74), the shelving units can be attached to those holes in the same manner in which the shelving units can be attached to holes 26.

A further advantage of some of the embodiments of this invention is that industry standard mounting hardware can be used to attach the brackets of those embodiments to a server or IT rack.

What has been described and illustrated herein are preferred embodiments of the invention along with some variations. The terms, descriptions and figures herein are set forth by way of illustration only and are not meant as limitations. Those skilled in the art will recognize that many variations are possible within the spirit and scope of the invention, which is intended to be defined by the following claims—and their equivalents—in which all terms are meant in their broadest reasonable sense unless otherwise indicated.

What is claimed is:

1. A cooling system for a server or IT rack comprising:
two spaced structural members of the server or IT rack; and
a panel that is rotatably attached to one of the two spaced structural members by a bracket and has open and closed positions, the panel rotating about a vertical axis between the open and closed positions;
the panel extending toward the other of the two spaced structural members when in the closed position and not extending toward the other of the two spaced structural members when in the open position.

2. The cooling system of claim 1, wherein:
the two spaced structural members are vertical rails having a front flange, each of the front flanges having a column of vertically spaced holes; and
the bracket is attached to one of the vertical rails using at least one of the vertically spaced holes.

3. The cooling system of claim 2, wherein:
the bracket includes a front portion that is attached to the front flange of one of the vertical rails, a hinge portion to which the panel is rotatably attached, and a back portion with bracket openings that replicate some of the vertically spaced holes in the front flanges, the bracket openings being spaced from the front portion.

4. The cooling system of claim 2, wherein:
the bracket engages the at least one of the vertically spaced holes of the front flange of one of the vertical rails.

5. The cooling system of claim 4, wherein:
the bracket includes at least one protrusion received in the at least one of the vertically spaced holes of the front flange of one of the vertical rails.

6. The cooling system of claim 5, wherein:
the at least one protrusion extends all the way through the at least one of the vertically spaced holes of the front flange of one of the vertical rails.

7. The cooling system of claim 6, wherein:
the at least one protrusion includes at least one hook that is received in the at least one of the vertically spaced holes of the front flange of one of the vertical rails and engages the front flange of the one of the vertical rails when in the closed position.

8. The cooling system of claim 2, wherein:
the panel is an elongated panel that extends between the two vertical rails when in the closed position.

9. The cooling system of claim 8, wherein:
the panel blocks airflow through the server or IT rack when in the closed positions and permits airflow through the server or IT rack when in the open position.

10. The cooling system of claim 1, further comprising:
a spring that biases the panel in the closed position.

11. The cooling system of claim 8, wherein:
the panel includes first and second ends and recessed portions at the first and second ends that receive the two vertical rails when the panel is in the closed position.

12. The cooling system of claim 8, wherein:
the panel includes at least one tab that is configured to be received in and engage one of the vertically spaced holes when the panel is in the closed position.

13. The cooling system of claim 8, wherein:
the panel includes a seal along one of its edges.

14. The cooling system of claim 11, wherein:
the panel includes at least one tab that is configured to be received in and engage one of the vertically spaced holes when the panel is in the closed position, the at least one tab being located at one of the recessed portions.

15. A method for selectively preventing or at least partially blocking cooling air from passing through a space in a server or IT rack between two vertical rails of the server or IT rack, including the steps of:
providing a panel that is rotatably attached to one of the two vertical rails by a bracket, the panel being rotatable about a vertical axis, the panel having a length substantially equal to the distance between the two vertical rails; and
rotating the panel between a closed portion in which the panel extends between the two vertical rails to block cooling air from passing through the space and an open position which permits the cooling air into the space.

16. The method of claim 15, wherein:
one of the vertical rails has a front flange with a column of vertically spaced holes; and
the bracket is attached to one of the vertical rails using at least one of the vertically spaced holes.

17. The method of claim 16, wherein:
the bracket includes a front portion that is attached to the front flange of one of the vertical rails, a hinge portion to which the panel is rotatably attached, and a back portion with bracket openings that replicate some of the vertically spaced holes in the front flanges, the bracket openings being spaced from the front portion.

18. The method of claim 17, wherein:
the panel is placed in the closed position when there is no computer or other electronic equipment in the space and in the open position when there is computer or other electronic equipment in the space.

19. The method of claim 18, wherein:
the panel includes first and second ends, each having a recessed portion; and
the vertical rails are received in the recessed portions when the panel is in the closed position.

20. The method of claim 20, wherein:
the panel includes at least one tab that is received in and engages one of the vertically spaced holes when the panel is in the closed position.

21. A cooling system for a server or IT rack comprising:
an opening in the server or IT rack for the passage of cooling air through the opening; and
a panel that is rotatably attached to the server or IT rack about a vertical axis and is rotatable between open and closed positions;
wherein when the panel is in the closed position the panel impedes the flow of cooling air through the opening and when the panel is in the open position the panel does not impede the flow of cooling air through the opening.
